(19) United States
(12) Patent Application Publication
(10) Pub. No.: US 2026/0056261 A1
(43) Pub. Date: Feb. 26, 2026

(54) SYSTEM AND METHOD FOR MONITORING BATTERY CELL HEALTH

(71) Applicant: Solid Power Operating, Inc., Louisville, CO (US)

(72) Inventor: Forrest A.L. Laskowski, Bend, OR (US)

(21) Appl. No.: 19/305,051

(22) Filed: Aug. 20, 2025

Related U.S. Application Data
(60) Provisional application No. 63/686,513, filed on Aug. 23, 2024.

(51) Int. Cl. G01R 31/392; G01R 31/3842; G01R 31/396

(52) U.S. Cl. CPC G01R 31/392; G01R 31/3842; G01R 31/396

(57) ABSTRACT

A method comprises charging the power source from a first state of charge to an upper voltage capacity value during a first charge-discharge cycle, measuring a first parameter value during the charging of the power source to the upper voltage capacity value during the first charge-discharge cycle, discharging the power source from a second state of charge to a lower voltage capacity value during the first charge-discharge cycle, the second state of charge lower than the second state of charge. The method also comprises measuring a second parameter value during the discharging of the power source to the lower voltage capacity value during the first charge-discharge cycle, measuring an overpotential value of the power source during the first charge-discharge cycle, and determining, based on each of the first parameter value, the second parameter value, and the overpotential value, a condition indicating a cell degradation of the power source.

### CROSS-REFERENCE TO RELATED APPLICATIONS

This application claims the benefit of and priority to U.S. Application No. 63/686,513, filed Aug. 23, 2024. The entire disclosure of the above application is incorporated herein by reference.

### TECHNICAL FIELD

Aspects of the disclosure relate to battery-type voltage sources, and more particularly to monitoring cell health in a battery.

### BACKGROUND

With the ever-increasing adoption of mobile devices, electric automobiles, and the development of Internet-of-Things devices, the need for battery technologies with improved reliability, capacity (Ah), thermal characteristics, lifetime and recharge performance has never been greater. While some battery technologies offer potential increases in safety, packaging efficiency, and enable new high-energy chemistries, further improvements are needed.

In one example, battery thermal runaway is a phenomenon that can occur when internal heating causes heat-generating reactions within the battery, leading to self-sustaining reactivity that can cause the battery to catch fire or explode. The initial heating event may be caused by unforeseeable reactions within the cell, by common abuse conditions (e.g. short circuit testing), or by external heat. Once a sufficient internal temperature is reached, a domino-like effect occurs where unwanted side reactions continually produce more heat, thereby triggering additional nearby reactions. In battery packs, the rise in temperature can also affect nearby batteries, causing the entire battery system to catch fire.

In another example, though a battery may not experience thermal runaway, reactions within the battery cells that result from charging and discharging the cells may lead to a degradation of the charge and discharge capacity. Eventually, a battery may simply lose its ability to hold a charge and/or supply power as previously able.

It is with these observations in mind, among others, that aspects of the present disclosure were conceived.

### Overview

In accordance with one aspect of the present disclosure, a method for a power source comprises charging the power source from a first state of charge to an upper voltage capacity value during a first charge-discharge cycle, the upper voltage capacity value higher than a value of the first state of charge, measuring a first parameter value during the charging of the power source to the upper voltage capacity value during the first charge-discharge cycle, discharging the power source from a second state of charge to a lower voltage capacity value during the first charge-discharge cycle, the second state of charge lower than the second state of charge. The method also comprises measuring a second parameter value during the discharging of the power source to the lower voltage capacity value during the first charge-discharge cycle, measuring an overpotential value of the power source during the first charge-discharge cycle, and determining, based on each of the first parameter value, the second parameter value, and the overpotential value, a condition indicating a cell degradation of the power source.

In accordance with another aspect of the present disclosure, a method for determining a degradation of a battery comprises charging the battery over a plurality of charge cycles, storing a plurality of charge capacity values over the plurality of charge cycles, discharging the battery over a plurality of discharge cycles storing a plurality of discharge capacity values over the plurality of discharge cycles, storing a plurality of overpotential values over one of the plurality of charge cycles and the plurality of discharge cycles, determining a first comparison value between a first charge capacity value of the plurality of charge capacity values and a grouped value of a subset of charge capacity values of the plurality of charge capacity values, determining a second comparison value between a first discharge capacity value of the plurality of discharge capacity values and a grouped value of a subset of discharge capacity values of the plurality of discharge capacity values, determining a third comparison value between a first overpotential value of the plurality of overpotential values and a grouped value of a subset of overpotential values of the plurality of overpotential values, and determining a degradation of the battery based on the first comparison value, the second comparison value, and the third comparison value.

In accordance with another aspect of the present disclosure, a system comprises a DC power source, a load, and a controller configured to measure a first parameter value of DC power source charging during each of a plurality of charge cycles, control the load to discharge the DC power source over a plurality of discharge cycles, measure a second parameter value of DC power source discharging during each of a plurality of discharge cycles, measure a third parameter value of DC power source overvoltage after each of one of the plurality of charge cycles and the plurality of discharge cycles, determine, based on each of the first, second, and third parameter values, a cell degradation of at least one cell of the DC power source.

### BRIEF DESCRIPTION OF THE DRAWINGS

The drawings illustrate embodiments presently contemplated for carrying out the invention.

In the drawings:

FIG. 1 illustrates a schematic representation of a DC power system according to one or more aspects of this disclosure.

FIG. 2 is a block diagram of a battery-type power source according to one or more aspects of this disclosure.

FIG. 3 is a block diagram showing a battery cell arrangement according to one or more aspects of this disclosure.

FIG. 4 is a flowchart showing a method for detecting a potential degradation condition of a battery according to one or more aspects of this disclosure.

FIG. 5 is a chart showing one example of voltage signals of one or more cells of a battery over multiple charge/discharge cycles according to one or more aspects of this disclosure.

FIG. 6 is a block diagram showing voltage measurement options according to one or more aspects of this disclosure.

FIG. 7 is a flowchart showing a method for detecting a potential degradation condition of a battery according to one or more additional aspects of this disclosure.

FIG. 8 is a graph showing current waveforms during a portion of a charging cycle according to one or more aspects of this disclosure.

FIG. 9 is a graph showing current waveforms during a portion of a charging cycle according to one or more additional aspects of this disclosure.

FIG. 10 is a flowchart showing a method for detecting a potential degradation condition of a battery according to one or more additional aspects of this disclosure.

FIG. 11 is a graph showing a baseline impedance spectroscopy waveform according to one or more aspects of this disclosure.

FIG. 12 is a graph showing an impedance spectroscopy waveform indicating a potential degradation condition of a battery according to one or more aspects of this disclosure.

FIG. 13 is a block diagram illustrating an example computing system according to one or more aspects of this disclosure.

### DETAILED DESCRIPTION

Examples of the present disclosure will now be described more fully with reference to the accompanying drawings. The following description is merely exemplary in nature and is not intended to limit the present disclosure, application, or uses.

Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Although the disclosure hereof is detailed and exact to enable those skilled in the art to practice the invention, the physical embodiments herein disclosed merely exemplify the invention which may be embodied in other specific structures. While the preferred embodiment has been described, the details may be changed without departing from the invention, which is defined by the claims.

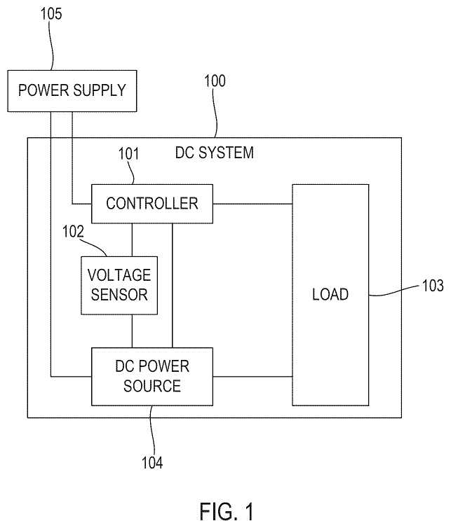

FIG. 1 illustrates a schematic representation of a direct current (DC) power system 100 configured to regulate and monitor electrical energy distribution within a DC environment. The system includes a controller 101 that serves as the central processing unit of the system, executing control algorithms and decision logic to maintain optimal performance. The controller 101 receives input signals from a voltage sensor 102 and other system components, enabling real-time adjustments to power flow and system parameters.

The controller 101 is also connected to a load 103 configured to receive power from a DC power source 104. In one embodiment, the DC power source 104 is rechargeable via a power supply unit 105 coupleable with the DC power system 100. The power supply unit 105 may be an external unit coupled with the DC power system 100 as needed for recharging of the DC power source 104, or the power supply unit 105 may be incorporated within the DC power system 100 on a permanent basis. The power supply unit 105 may be a voltage-to-voltage converter configured to convert an input electrical power (e.g., AC power from a power grid) into a DC power sufficient to provide charging energy to the DC power source 104. Alternatively, the power supply unit 105 may be a generator configured to convert an input mechanical power into the DC power sufficient to provide charging energy to the DC power source 104.

The DC power source 104 may include one or more energy generation or storage devices, such as batteries, photovoltaic cells, or fuel cells, configured to deliver direct current to the load 103, which represents any electrical or electronic device, subsystem, or network that consumes DC power, and may vary in demand depending on operational conditions.

The voltage sensor 102 monitors the voltage level across critical nodes within the system and, as described hereinbelow, within substructures of the DC power source 104. The voltage sensor 102 provides feedback to the controller 101 to ensure voltage stability, prevent overvoltage or undervoltage conditions, and support fault detection protocols.

Interconnections between these components are configured to support bidirectional communication and power flow, enabling dynamic response to changing load conditions, energy availability, and system health. The schematic layout depicted in FIG. 1 is exemplary and may be adapted to various configurations depending on application-specific requirements.

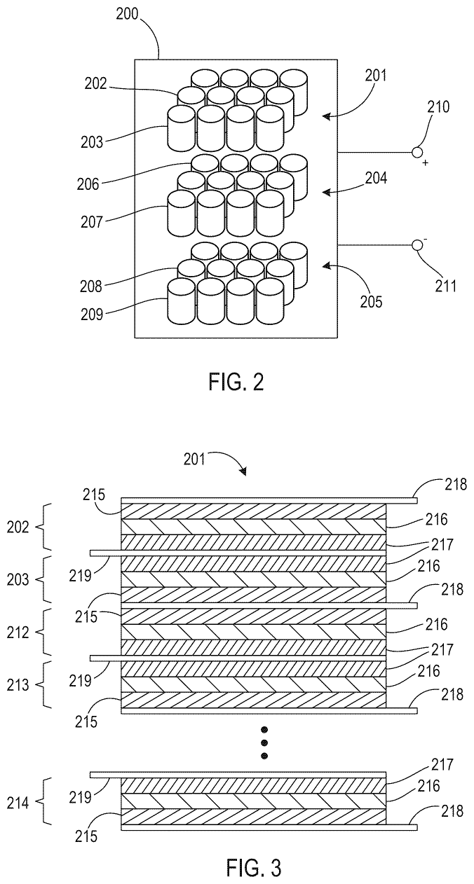

FIG. 2 illustrates a block diagram of a battery-type power source 200 according to one or more aspects of this disclosure. The battery power source 200 may represent, in one example, the DC power source 104 of FIG. 1. As shown, several cells are joined together in packs. A first pack 201 includes cells (such as cells 202, 203) joined together to produce a first voltage source capable of supplying voltages between a first fully-charged voltage level and a first fully-discharged voltage level. The cells 202, 203 are joined in an arrangement of parallel and/or series connections sufficient to source voltage between the designed charged/discharged voltage levels. Additional packs (such as packs 204, 205) contain respective cells 206/207 and 208/209 also configured to supply fully-charged through fully-discharged voltages. It may be desired that each cell and each pack yield substantially similar values when compared with one another. The packs 201, 204, 205, when combined, supply a battery voltage on output terminal 210, 211.

In one embodiment, the battery power source 200 is an all-solid-state battery, and each cell 202-203, 206-209 is an all-solid-state battery cell. FIG. 3 illustrates a block diagram showing a battery cell arrangement according to one or more aspects of this disclosure. In the illustrated diagram, first pack 201 is represented. However, it is contemplated that FIG. 3 may represent any of the packs within the battery power source 200.

Referring to FIGS. 2 and 3, as shown, the pack 201 includes a plurality of cells 202, 203, 212, 213, 214, each having a respective anode 215, separator 216, and cathode 217. An anode current collector 218 is electrically coupled to each anode 215, and a cathode current collector 219 is electrically coupled to each cathode 217. According to a first example, the anode current collector 218 is a positive electrode formed from a copper sheet coated with an anode electrolyte (e.g., a positive electrode active material) such as one having lithium sulfide or another lithium-based compound. The copper sheet may be coated on both sides with the anode electrolyte in preparation for stacking the layers as shown in FIG. 3. In this example, the cathode current collector 219 is a negative electrode formed from an aluminum sheet coated with a cathode electrolyte (e.g., a negative electrode active material), and the separator 216 is a solid electrolyte layer. Forming the pack 201 may include stacking a number of coated anode and cathode sheets with the separator 216 separating each layer.

Each cell 202, 203, 212, 213, 214 produces a voltage at the cell level, and together, they produce a pack voltage. Referring as well to FIG. 2, the number of cells illustrated in FIG. 3 matches the number of cells illustrated in each pack 201, 204, 205. While twelve cells are illustrated in FIG. 2 for purposes of discussion herein, it is contemplated that the number of individual cells in each pack 201, 204, 205 may be more or less than that shown and discussed.

In a battery power source such as the source 200 discussed herein, an overpotential occurs that is understood as the potential difference (or voltage measurement difference) between a thermodynamically determined voltage for a given state of charge (determined when the cell is at rest) and the voltage observed during charge or discharge at the same given state of charge. For a rechargeable battery such as the battery power source 200, the battery acts as a galvanic cell that converts chemical energy into electrical energy when discharging. That is, the battery acts as a galvanic cell when it is providing output voltage. When being charged, the battery acts as an electrolytic cell as it converts electrical energy provided to the cell to chemical energy. The conversions between electrical and chemical energy are known as a redox reaction. A redox reaction is a process where oxidation and reduction occur simultaneously. Oxidation is a process in which a substance loses electrons. Reduction is a process in which a substance gains electrons.

Electrolysis in an electrolytic cell occurs when DC current is applied through the electrolyte, resulting in a chemical reaction between electrodes and the separation of elements (molecules, atoms and ions). During this process, a transfer of electrons also occurs at the anode and cathode. A decomposition potential is the voltage needed for electrolysis to occur. The potential difference between decomposition potential (actual voltage) and the reduction potential (thermodynamically determined) is the overpotential required for decomposition.

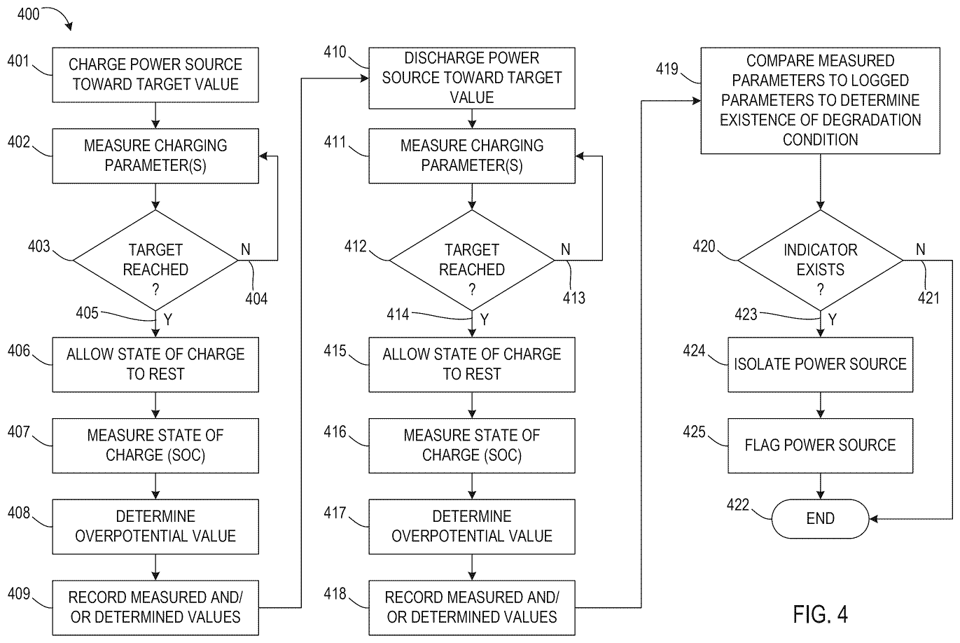

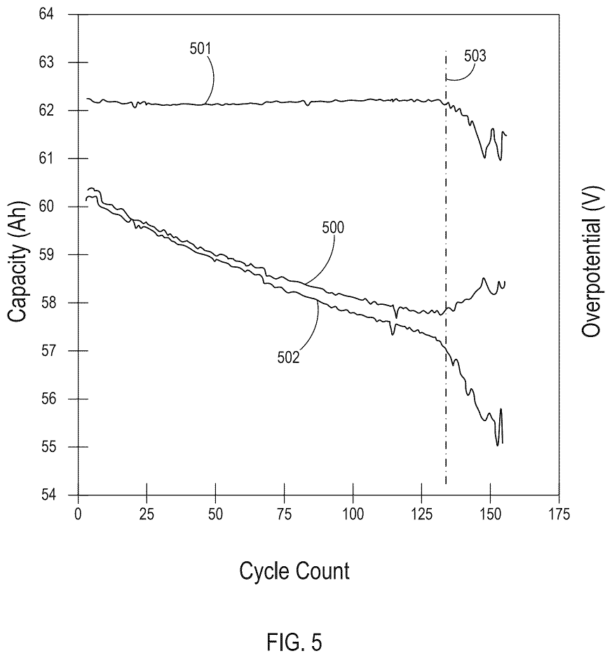

By measuring certain aspects of the cells as described herein, conditions related to battery degradation (e.g., imminent thermal runaway, loss of charge capacity, etc.) can be anticipated and prevented. FIG. 4 illustrates a flowchart showing one method 400 for diagnosing and monitoring cell degradation of a power source, such as a solid-state battery, according to one or more aspects of this disclosure. The method 400 includes determining cell degradation over time through analysis of charge-discharge behavior and overpotential characteristics. Through the processing of the method 400, charge, discharge, and overpotential values are measured, calculated, and stored. FIG. 5 illustrates a plot showing exemplary measured and stored charge, discharge, and overpotential values based on one or more portions of the method 400 of FIG. 4.

Referring to both FIGS. 4 and 5, the method 400 includes obtaining one or more parameters associated with a battery charging cycle. During the charging cycle, the battery (e.g., the DC power source 104 of FIG. 1) is charged via a power source (e.g., the power supply unit 105 of FIG. 1) from a first state of charge to a target, second state of charge (step 401). In a preferred embodiment, the first state of charge begins at a lowest charge level of the battery (e.g., a lower voltage capacity value). However, the charge cycle may begin with the battery state of charge being higher than the lowest charge level. During the charging cycle, the voltage of the battery is raised toward the target capacity such as an upper voltage capacity value. This upper voltage capacity value is greater than the initial state of charge, indicating a full or near-full charge condition. The upper voltage capacity value may represent the highest design charge level of the battery. During this charging cycle phase, one or more parameters are measured (step 402). One of the measured parameters may represent a duration of time required to reach the upper voltage capacity from the beginning of the charge cycle. Another measured parameter may represent an amount of electrical charge delivered during the charge cycle. A combination of the duration of time and the amount of electrical charge may be combined into a unit of electric charge, having dimensions of electric current multiplied by time.

At step 403, the charging cycle is evaluated to determine whether the target state of charge has been reached. If not (404), process control returns step 402 to keep the measurements going during the charging cycle. In response to reaching (405) the target charging voltage (e.g., the upper voltage capacity of the battery), the charging cycle is ceased to allow the state of charge to rest at step 406. The resting period allows the potential to settle to the thermodynamic limit which allows for the calculation of the overpotential at the state of charge. At step 407, the voltage or state of charge of the target power source is measured.

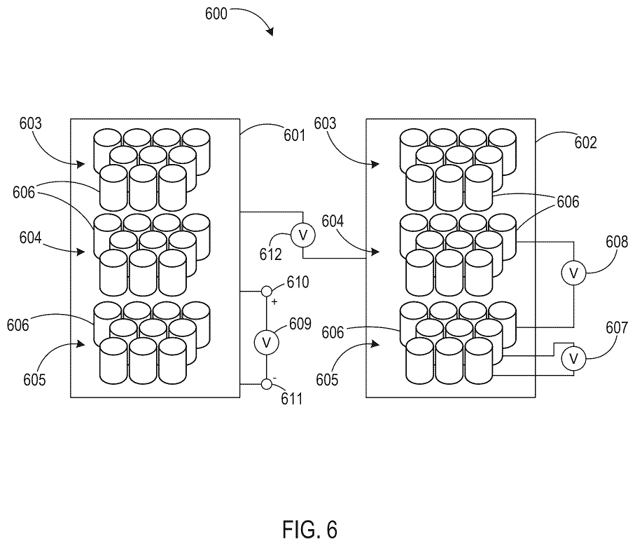

Referring to FIG. 6, a block diagram is shown of a variety of voltage measurement options according to one or more aspects of this disclosure. A battery system 600 is shown including a pair of batteries 601, 602 that may be similar to battery power source 200 of FIG. 2. For example, each battery 601, 602 includes a plurality of packs pack 603, 604, 605 of cells 606. As contemplated herein, the method 400 and determination of thermal runaway factors may be performed on a cell level, a pack level, a battery level, and/or on a system level. To perform overpotential voltage measurements on the cell level in one example, a voltage measurement device 607 is connected to one or more of the individual cells 606 of a pack. Multiple voltage measurement devices 607 may be used for a single pack, and multiple packs may include cell level voltage measurements. In another example, a voltage measurement device 608 is connected between multiple packs such as between packs 604, 605 as illustrated. It is contemplated that multiple voltage measurement devices 608 may be used among the various packs within a battery (e.g., battery 601 or battery 602). In another example, a voltage measurement device 609 is coupled to output terminals 610, 611 of a battery (e.g., battery 601 or battery 602) for performing overpotential voltage measurements on the battery level. In yet another example, a voltage measurement device 612 is connected to the batteries 601, 602 for performing overpotential voltage measurements on the system level.

Returning to FIGS. 4 and 5, the state of charge measured at step 407 is compared with the target state of charge. A difference between the state of charge measured at step 407 and the target state of charge is determined (step 408) as the overpotential value for the charging cycle of steps 401-406. The settled state of charge after the resting period after the charging cycle is typically lower than the target state of charge. The measured parameter(s) (e.g., time, current) obtained during the charging cycle and the measured and determined overpotential value are stored (step 409) in respective logs or lists of historical values. A first curve 500 illustrated in FIG. 5 represents a historical log of energy (e.g., capacity (Ah)) measurements obtained over a plurality of charge cycles. In one embodiment, a second curve 501 represents a historical log of overpotential values obtained over a plurality of charge cycles. However, as described below, overpotential values may be obtained following discharge cycles, and the curve 501 may represent those overpotential values in another embodiment.

Following the charging phase, the power source is discharged (step 410) from the charged state of charge toward a lower state of charge (e.g., the lower voltage capacity value). The lower voltage capacity value may represent the lowest design charge level of the battery. During this discharge phase, the same parameter values as those measured during the charging cycle are measured (step 411) during the discharging cycle, which may similarly represent either a time duration or a quantity of electrical charge extracted.

At step 412, the discharging cycle is evaluated to determine whether the target state of charge has been reached. If not (413), process control returns step 411 to keep the measurements going during the discharging cycle. In response to reaching (414) the target charging voltage (e.g., the lower voltage capacity of the battery), the discharging cycle is ceased to allow the state of charge to rest at step 415. At step 416, the voltage or state of charge of the target power source is measured.

The state of charge measured at step 416 is compared with the target state of charge. A difference between the state of charge measured at step 416 and the target state of charge is determined (step 417) as the overpotential value for the discharging cycle of steps 410-415. The settled state of charge after the resting period after the discharging cycle is typically higher than the target state of charge. The measured parameter(s) (e.g., time, current) obtained during the discharging cycle and the measured and determined overpotential value are stored (step 418) in respective logs or lists of historical values. A third curve 502 illustrated in FIG. 5 represents a historical log of energy (e.g., capacity (Ah)) measurements obtained over a plurality of discharge cycles. Further, the second curve 501 may represent, in another embodiment, the historical log of overpotential values measured after discharging cycles as described above.

Based on the parameter value measured during the charge and discharge cycles of a charge-discharge cycle and the overpotential value determined either after the charging cycle or after the discharge cycle of the charge-discharge cycle, the method 400 determines (step 419) a condition indicative of cell degradation. This determination includes incorporating subsets of the historical logs of each parameter across multiple charge-discharge cycles.

To assess degradation, the parameter values from a given charge-discharge cycle (e.g., the most recent charge-discharge cycle) are compared to average values derived from the respective subsets of the historical logs. For example, the measured parameter value of the charge cycle portion of the charge-discharge cycle is compared to an average of a number of the next-most recent stored charge cycle parameter values (e.g., as shown in previous cycles in the first curve 500 and represented in the respective subset of historical log values). This comparison generates a value indicating whether the charging cycle parameter value is higher or lower than the average historical charging cycle parameter values.

The measured parameter value of the discharge cycle portion of the charge-discharge cycle is similarly compared to an average of a number of the next-most recent stored discharge cycle parameter values (e.g., as shown in previous cycles in the third curve 502). This comparison generates a value indicating whether the discharging cycle parameter value is higher or lower than the average historical discharging cycle parameter values. Additionally, the determined overpotential value for the charge-discharge cycle is compared to an average of a number of the next-most recent stored overpotential values (e.g., as shown in previous cycles in the second curve 501). In one embodiment, the number of values in each of the subsets of values corresponds to the next-most recent five values. By including an average of these values, individual anomalies or one-off aberrations in any particular charging cycle or discharging cycle may be minimized.

A degradation condition is determined based on a value of the measured parameter value of the charge cycle portion being greater than the corresponding average subset value, a value of the measured parameter value of the discharge cycle portion being less than the corresponding average subset value, and the value of the determined overpotential value being less than the corresponding average subset value. As shown in FIG. 5, a threshold 503 indicates a cycle at which a degradation condition may be determined in an example. The amount of difference between the tested values and their respective average subset values may be chosen to indicate a greater chance of determining a degradation trend in the data. For example, the measured charging and discharging cycle parameters and the calculated overpotential value may be considered to be indicative of a degradation condition based on a difference of greater than five percent of the respective values.

These comparative metrics provide a robust indication of declining cell performance, such as increased resistance, reduced capacity, or diminished voltage recovery. The method 400 is particularly applicable to solid-state batteries, where precise monitoring of charge dynamics and overpotential behavior is critical for long-term reliability and predictive maintenance.

At step 420, the existence of a degradation condition is tested. If no degradation condition is determined (421) based on the comparison in step 419, such as when any of the compared values does not follow the test that the charge capacity is greater than the average, the discharge capacity is lower than the average, or the overpotential value is lower than the average, no degradation condition indicator is determined to exist, and the method 400 ends (step 422).

If a degradation condition indicator is indicated (423) by an analysis of the data, additional steps can be performed to reduce the chance of the battery actually experiencing an undesirable condition (e.g., a thermal runaway or a loss of function). For example, at step 424, the power source that may be subject to the degradation condition may be isolated from the pack, battery, or system by removing the power source from any connection to other components and from any additional charge or discharge cycle. Further, at step 425, the threatened power source may be flagged in software for display to a user to allow replacement of the unhealthy power source with a healthy one.

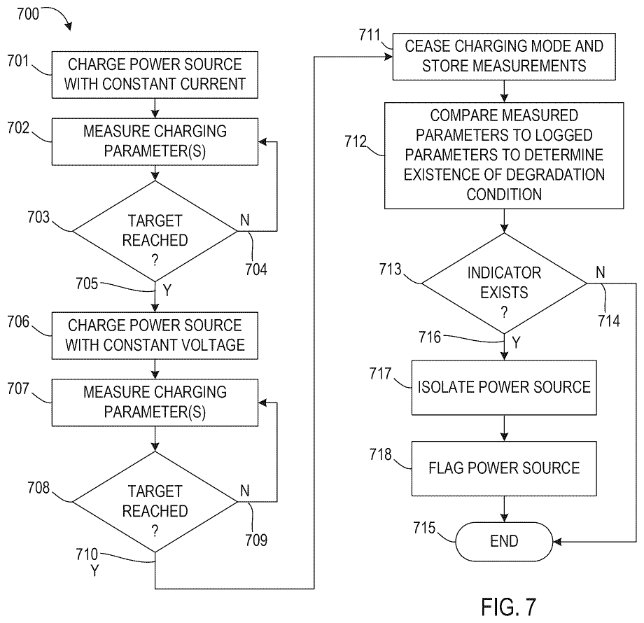

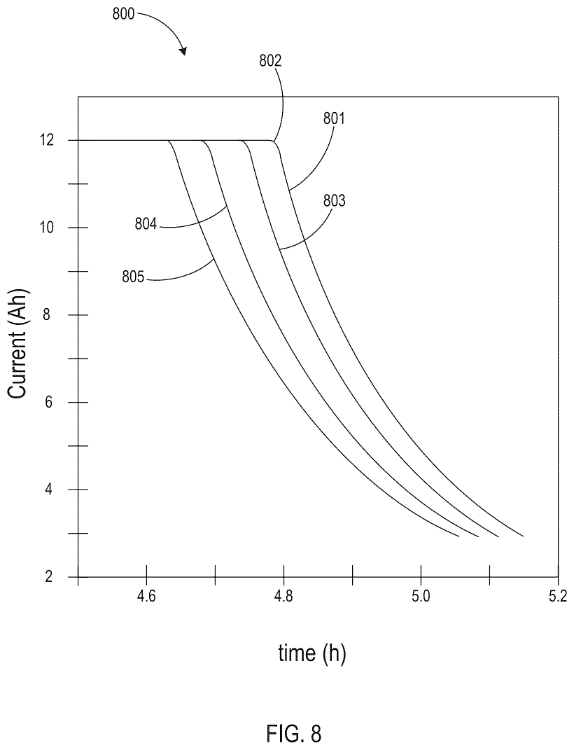

FIG. 7 illustrates a flowchart showing one method 700 for diagnosing and monitoring cell degradation of a power source, such as a solid-state battery, according to one or more aspects of this disclosure. The method 700 includes determining cell degradation over time through analysis of charge-discharge behavior and overpotential characteristics. Through the processing of the method 700, charge, discharge, and overpotential values are measured, calculated, and stored. FIG. 8 illustrates a graph 800 showing current waveforms during a portion of a charging cycle based on one or more portions of the method 700 of FIG. 7 according to one or more aspects of this disclosure.

Referring to both FIGS. 7 and 8, the method 700 includes obtaining parameters associated with a battery charging cycle. During the charging cycle, the battery (e.g., the DC power source 104 of FIG. 1) is charged via a power source (e.g., the power supply unit 105 of FIG. 1) from a first state of charge to a target, second state of charge (step 701) such as 4.1 V in an example. During the charging cycle, the voltage of the battery is raised toward the target capacity such as an upper voltage capacity value using a constant current. One example, shown in FIG. 8, uses a constant current of 12 A. This upper voltage capacity value indicates a full or near-full charge condition. The upper voltage capacity value may represent the highest design charge level of the battery. During this charging cycle phase, one or more parameters are measured (step 702). One of the measured parameters may be the current supplied to the battery during the charge.

At step 703, the charging cycle is evaluated to determine whether the target state of charge has been reached. If not (704), process control returns step 702 to keep the measurements going during the charging cycle. A first charging curve 801 graphically illustrates reaching the target state of charge at a corner point 802 in the curve. At this point, the voltage of the battery has reached the target state of charge using the constant current mode.

In response to reaching (705) the target charging voltage (e.g., the upper voltage capacity of the battery), the charging mode switches to a constant voltage mode where the current required to maintain the state of charge of the battery is varied. Accordingly, during this portion of the charging cycle, the battery is charged (step 706) until a target current is reached. The target current may represent a lower current cutoff for the completion of the charging process. The supplied current is still measured (step 707) during the constant voltage charging phase. At step 708, the charging cycle is evaluated to determine whether the target (e.g., cutoff) current has been reached. If not (709), process control returns step 707 to keep the measurements going during the charging cycle. In response to reaching (710) the target current, the charging is stopped at step 711. Further, step 711 includes storing the measured parameter(s) (e.g., current) obtained during the charging cycle in a log or list of historical values.

As shown in FIG. 8, many charging curves may be measured and stored during many respective charging cycles. In an example, FIG. 8 illustrates four charging curves 801 and 803-805 measured during, for example, charging cycles corresponding with a 3rd, 25th, 50th, and 75th charging cycle. As shown, changes to the battery over time affect the ability of the battery to accept a charge. It can be expected that succeeding charge cycles experience a shift to the left as the battery ages. That is, a loss of capacity cycle-over-cycle exhibits a normal behavior of a typical battery. The charge curves in successive charge cycles may be very close to one another yet still be shifted from each other. A dramatic shift among the curves is illustrated in FIG. 8, for example, by showing exemplary curves (801, 803-805) many (e.g., about twenty five) charging cycles apart.

The charging curves 801, 803-805 shown in FIG. 8 represent an expected change within the battery as it ages. Once the constant voltage charging mode begins, each curve 801, 803-805 is in its own portion of the graph 800 and does not overlap any other. However, if the battery begins to experience undesirable side reactions, such side reactions can eventually lead to undesirable battery conditions such as thermal runaway, loss of charge capacity, etc. Such side reactions may be, for example, Li plating at/within the anode, oxidation of binder species within the cathode, and electrochemical decomposition of electrolyte.

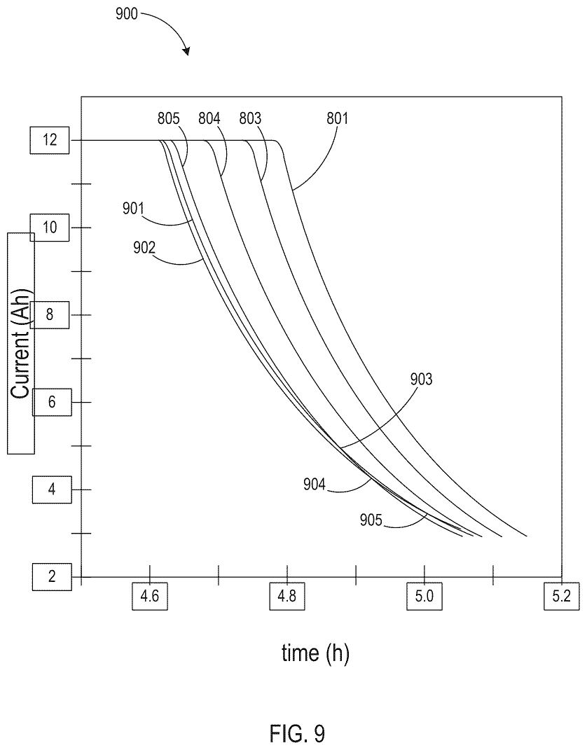

The presence of one or more such side reactions in a battery under charge may be exhibited in the crossing of charging curves. That is, a charging curve of a later charging cycle may cross one or more of the charging curves of previous charging cycles. In an example illustration, FIG. 9 shows a graph 900 illustrating the charging curves 801, 803-805 of FIG. 8 as well as two additional charging curves 901, 902 that cross one or more previously measured charging curves. The charging curve 901 may represent, for example, a 95th charging cycle of the battery. Due to the formation and effects of one or more side reactions presenting themselves within the battery, the charging curve 901 experiences a charging reaction that causes the current supplied to the battery during the constant voltage phase (step 706 of FIG. 7) that currents supplied to the battery after a crossing point 903 to happen at a longer time than with one or more of the previous charging curves of earlier charging cycles. As shown, the crossing point 903 shows a cross of the charging curve 901 with the 75th charging curve 805. Though every charging cycle through the 95th charging cycle is not shown for simplification purposes, it is understood that, being the 95th charging cycle, at least charging cycles 76-94 (as well as cycles earlier than 75) would also be crossed. As a further example, the charging curve 902, which may represent a 96th charging cycle, is shown to cross the charging curves 901 (at crossing point 904) and 805 (at crossing point 905). The existence of crossing points 903-905 and others indicates a degradation condition of the battery.

Returning to FIG. 7, based on the stored charge current parameter values measured during the charging cycles, the method 700 determines (step 712) a condition indicative of cell degradation. To assess degradation, the current parameter values from a given charging cycle are compared to the current parameter values from an earlier charging cycle. For example, the measured current parameter values from the most recent charging cycle are compared with those of the immediately prior charging cycle. The values are compared to determine whether the current values at same times show a longer time with the later charging cycle than with the earlier charging cycle.

At step 713, the existence of a degradation condition is tested. If no degradation condition is determined (714) based on the comparison in step 712, such as when any of the compared values does not cross a time point of a respective value of an earlier charging cycle, no degradation condition indicator is determined to exist, and the method 700 ends (step 715).

If a degradation condition indicator is indicated (716) by an analysis of the data, additional steps can be performed to reduce the chance of the battery actually experiencing an undesirable condition (e.g., a thermal runaway or a loss of function). For example, at step 717, the power source that may be subject to the degradation condition may be isolated from the pack, battery, or system by removing the power source from any connection to other components and from any additional charge or discharge cycle. Further, at step 718, the threatened power source may be flagged in software for display to a user to allow replacement of the unhealthy power source with a healthy one.

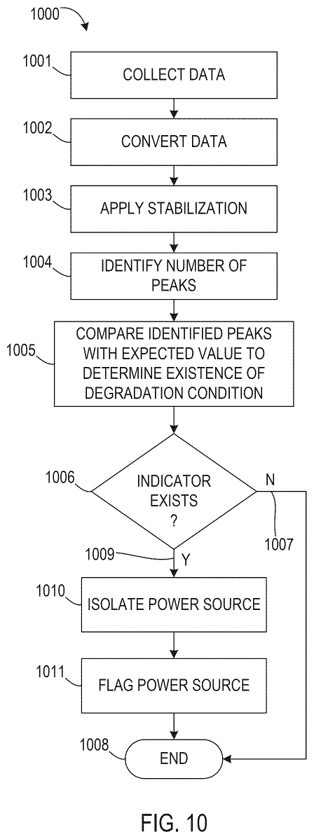

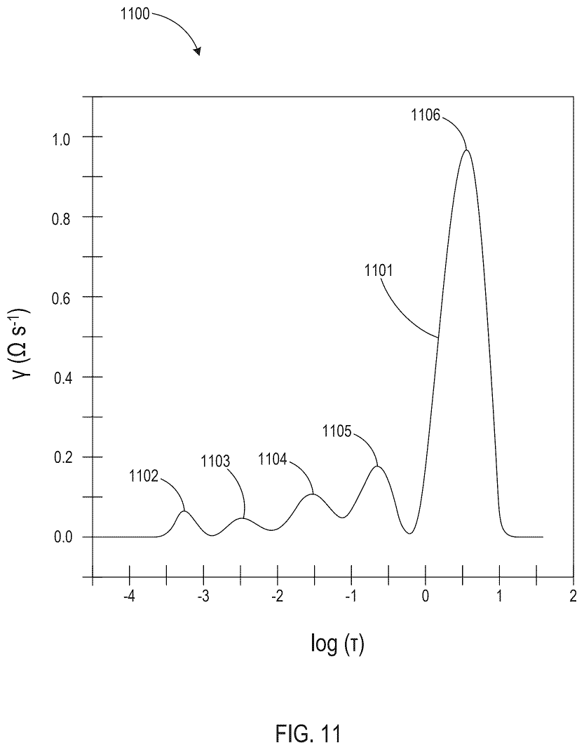

FIG. 10 illustrates a flowchart showing one method 1000 for diagnosing and monitoring cell degradation of a power source, such as a solid-state battery, according to one or more aspects of this disclosure. The method 1000 includes determining cell degradation through impedance spectroscopy analysis. FIG. 11 illustrates a graph 1100 showing an impedance spectroscopy curve 1101 based on one or more portions of the method 1000 of FIG. 10 according to one or more aspects of this disclosure.

Impedance spectroscopy includes analyzing impedance data of a battery in the time domain transformed from the frequency domain. One technique, referred to as Distribution of Relaxation Times (DRT), transforms impedance data from the frequency domain into the time domain and reveals how different processes within the battery relax over time. Each process is characterized by a relaxation time constant, and DRT provides a distribution of these constants. Referring to the impedance spectroscopy graph 1100, the relaxation time (r) is the time it takes for a system process to return to equilibrium after a disturbance. The vertical axis of the graph 1100 is a magnitude, G(r), at the given relaxation times. Peaks 1102-1106 of the impedance spectroscopy curve 1101 correspond to distinct physical or chemical processes.

Generating an impedance spectroscopy curve includes collecting data (step 1001) of a battery under test across a range of frequencies using techniques like Electrochemical Impedance Spectroscopy (EIS). The impedance reflects the system's response to an AC signal at different frequencies. At step 1002, the frequency-dependent impedance data is converted using DRT into a distribution of relaxation times G(r), where each T corresponds to a time constant of a physical process. This can include solving an inverse problem using, for example, a Fredholm integral equation of the first kind. At step 1003, data stabilization is used. In some cases, the transformation (e.g., step 1002) is mathematically ill-posed. Accordingly, regularization techniques like Tikhonov regularization, Bayesian inference, or maximum entropy are used to stabilize the solution. Such stabilization extract a smooth and interpretable distribution from noisy data.

Peaks in the DRT plot (e.g., peaks 1102-1106 of impedance spectroscopy curve 1101) correspond to distinct electrochemical processes (e.g., charge transfer, diffusion, double-layer capacitance). The location of each peak (in terms of t) indicates the characteristic time scale of that process. The height or area under the peak reflects the strength or contribution of that process to the overall impedance. For a given battery construction, it can be expected that the number of peaks in the DRT curve 1101 will remain the same over the life of the battery when functioning properly, indicating a consistent number of processes occurring. It can also be expected that, while the number of peaks remain the same, they may shift up or down the horizontal time axis as the battery ages. At step 1004, the number of peaks in the impedance spectroscopy curve are identified.

It has been found that a battery undergoing a degradation condition begins to produce additional peaks in the DRT spectrum. Therefore, at step 1005, the number of peaks identified in step 1004 is compared with an expected value to determine the existence of a degradation condition. In the examples herein, the number of identified peaks may be compared with the five peaks expected for the battery type under test. A degradation condition exists if an increase in the number of peaks is determined.

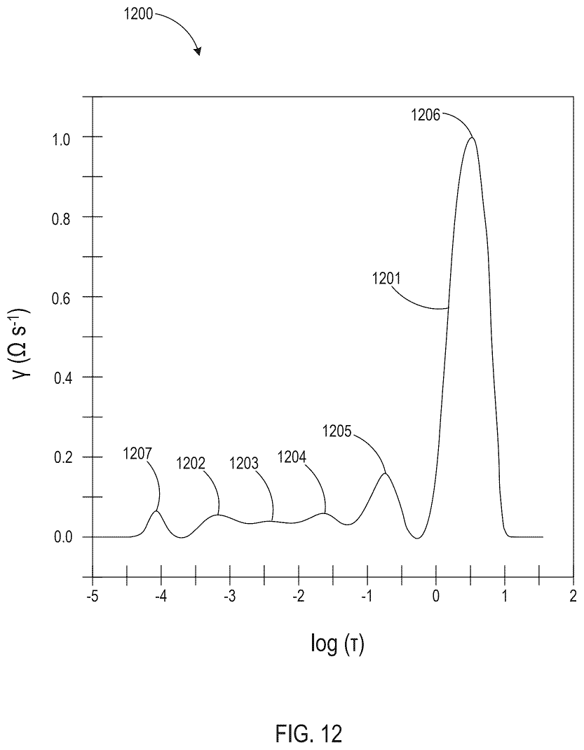

In an example showing more than five peaks, analysis the impedance spectroscopy curve 1200 of the impedance spectroscopy graph 1201 of FIG. 12 may identify six peaks 1202-1207 instead of the expected five peaks. Peaks 1202-1206 correspond to the processes identified in the impedance spectroscopy curve 1101 of FIG. 11. However, a new peak 1207 has identified itself during the analysis of method 1000.

At step 1006, the existence of a degradation condition is tested. If no degradation condition is determined (1007) based on the comparison in step 1005, such as when any of the compared values does not follow the test that the charge capacity is greater than the average, the discharge capacity is lower than the average, or the overpotential value is lower than the average, no degradation condition indicator is determined to exist, and the method 1000 ends (step 1008).

If a degradation condition indicator is indicated (1009) by an analysis of the data, additional steps can be performed to reduce the chance of the battery actually experiencing an undesirable condition (e.g., a thermal runaway or a loss of function). For example, at step 1010, the power source that may be subject to the degradation condition may be isolated from the pack, battery, or system by removing the power source from any connection to other components and from any additional charge or discharge cycle. Further, at step 1011, the threatened power source may be flagged in software for display to a user to allow replacement of the unhealthy power source with a healthy one.

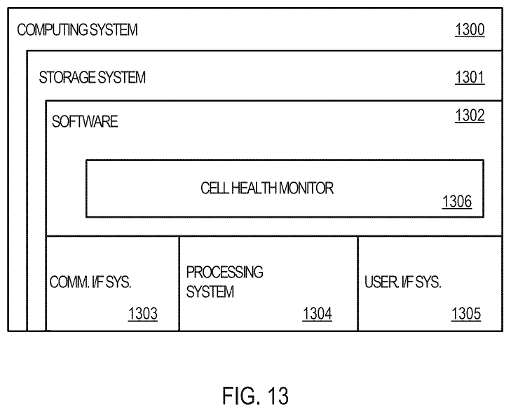

FIG. 13 illustrates a computing system 1300 to perform cell health monitoring according to an implementation of the present technology. Computing system 1300 is representative of any system or collection of systems with which the various operational architectures, processes, scenarios, and sequences disclosed herein for performing cell health monitoring processes may be employed. Computing system 1300 may be implemented as a single apparatus, system, or device or may be implemented in a distributed manner as multiple apparatuses, systems, or devices. Computing system 1300 includes, but is not limited to, storage system 1301, software 1302, communication interface system 1303, processing system 1304, and user interface system 1305 (optional). Processing system 1304 is operatively coupled with storage system 1301, communication interface system 1303, and user interface system 1305. Computing system 1300 may be representative of a cloud computing device, distributed computing device, or the like.

Processing system 1304 loads and executes software 1302 from storage system 1301. Software 1302 includes and implements cell health monitoring 1306, which is representative of any of the methods 400, 700, 1000 described herein. When executed by processing system 1304 to detect indicators of cell health degradation, software 1302 directs processing system 1304 to operate as described herein for at least the various processes, operational scenarios, and sequences discussed in the foregoing implementations. Computing system 1300 may optionally include additional devices, features, or functionality not discussed for purposes of brevity.

Referring still to FIG. 13, processing system 1304 may comprise a micro-processor and other circuitry that retrieves and executes software 1302 from storage system 1301. Processing system 1304 may be implemented within a single processing device but may also be distributed across multiple processing devices or sub-systems that cooperate in executing program instructions. Examples of processing system 1304 include general purpose central processing units, graphical processing units, application specific processors, and logic devices, as well as any other type of processing device, combinations, or variations thereof.

Storage system 1301 may comprise any computer readable storage media readable by processing system 1304 and capable of storing software 1302. Storage system 1301 may include volatile and nonvolatile, removable and non-removable media implemented in any method or technology for storage of information, such as computer readable instructions, data structures, program modules, or other data. Examples of storage media include random access memory, read only memory, magnetic disks, optical disks, optical media, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 1301 may also include computer readable communication media over which at least some of software 1302 may be communicated internally or externally. Storage system 1301 may be implemented as a single storage device but may also be implemented across multiple storage devices or sub-systems co-located or distributed relative to each other. Storage system 1301 may comprise additional elements, such as a controller capable of communicating with processing system 1304 or possibly other systems.

Software 1302 (including cell health monitoring 1306) may be implemented in program instructions and among other functions may, when executed by processing system 1304, direct processing system 1304 to operate as described with respect to the various operational scenarios, sequences, and processes illustrated herein. For example, software 1302 may include program instructions for implementing cell health monitoring processes as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 1302 may include additional processes, programs, or components, such as operating system software, virtualization software, or other application software. Software 1302 may also comprise firmware or some other form of machine-readable processing instructions executable by processing system 1304.

In general, software 1302 may, when loaded into processing system 1304 and executed, transform a suitable apparatus, system, or device (of which computing system 1300 is representative) overall from a general-purpose computing system into a special-purpose computing system customized to provide cell health monitoring process performance as described herein. Indeed, encoding software 1302 on storage system 1301 may transform the physical structure of storage system 1301. The specific transformation of the physical structure may depend on various factors in different implementations of this description. Examples of such factors may include, but are not limited to, the technology used to implement the storage media of storage system 1301 and whether the computer-storage media are characterized as primary or secondary storage, as well as other factors.

For example, if the computer readable storage media are implemented as semiconductor-based memory, software 1302 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 1303 may include communication connections and devices that allow for communication with other computing systems (not shown) over communication networks (not shown). Examples of connections and devices that together allow for inter-system communication may include network interface cards, antennas, power amplifiers, radiofrequency circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication interface system 1303 may communicate with sensors and input devices such as the voltage measurement devices 612 of FIG. 6. Additionally, it is observable that the ambient temperature affects battery overpotential. Accordingly, communication interface system 1303 may also communicate with one or more temperature sensors (not shown) to compare observed changes with the ambient temperature. In one embodiment, temperature calibration curves may be included and consulted to help determine what behavior a given battery should exhibit at a given cycle and temperature.

Communication between computing system 1300 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of networks, or variation thereof. The aforementioned communication networks and protocols are well known and need not be discussed at length here.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the present disclosure. Additionally, while various embodiments of the present disclosure have been described, it is to be understood that aspects of the present disclosure may include only some of the described embodiments. Accordingly, the invention is not to be seen as limited by the foregoing description but is only limited by the scope of the appended claims.

1. A method for a power source comprising:
charging the power source from a first state of charge to an upper voltage capacity value during a first charge-discharge cycle, the upper voltage capacity value higher than a value of the first state of charge;
measuring a first parameter value during the charging of the power source to the upper voltage capacity value during the first charge-discharge cycle;
discharging the power source from a second state of charge to a lower voltage capacity value during the first charge-discharge cycle, the second state of charge lower than the second state of charge;
measuring a second parameter value during the discharging of the power source to the lower voltage capacity value during the first charge-discharge cycle;
measuring an overpotential value of the power source during the first charge-discharge cycle; and
determining, based on each of the first parameter value, the second parameter value, and the overpotential value, a condition indicating a cell degradation of the power source.

2. The method of claim 1 further comprising:
generating a historical log of first parameter values measured over a plurality of charge-discharge cycles;
generating a historical log of second parameter values measured over the plurality of charge-discharge cycles; and
generating a historical log of overpotential values measured over the plurality charge-discharge cycles.

3. The method of claim 2, wherein determining the condition comprises:
comparing the first parameter value to an average value of a subset of first parameter values of the historical log of first parameter values;
comparing the second parameter value to an average value of a subset of second parameter values of the historical log of second parameter values;
comparing the overpotential value to an average value of a subset of the historical log of overpotential values; and
determining the condition based on:
the first parameter value being higher than the average value of the subset of first parameter values of the historical log of first parameter values;
the second parameter value being lower than the average value of the subset of second parameter values of the historical log of second parameter values; and
the overpotential value being lower than the average value of the subset of the historical log of overpotential values.

4. The method of claim 3, wherein the subset of first parameter values of the historical log of first parameter values comprises a first number of most-recent first parameter values of the historical log of first parameter values, the first number being less than a total number of first parameter values in the historical log of first parameter values;
wherein the subset of second parameter values of the historical log of second parameter values comprises a second number of most-recent second parameter values of the historical log of second parameter values, the second number being less than a total number of second parameter values in the historical log of second parameter values; and
wherein the subset of overpotential values of the historical log of overpotential values comprises a third number of most-recent overpotential values of the historical log of overpotential values, the third number being less than a total number of overpotential values in the historical log of overpotential values.

5. The method of claim 4, wherein the first number is equal to five;
wherein the second number is equal to five; and
wherein the third number is equal to five.

6. The method of claim 3, wherein determining the condition comprises determining the condition based on:
the first parameter value being five percent higher than the average value of the subset of first parameter values of the historical log of first parameter values;
the second parameter value being five percent lower than the average value of the subset of second parameter values of the historical log of second parameter values; and
the overpotential value being five percent lower than the average value of the subset of the historical log of overpotential values.

7. The method of claim 1, wherein the first state of charge is equal to the lower voltage capacity value.

8. The method of claim 1, wherein the first parameter value comprises a unit of time; and
wherein measuring the first parameter value comprises measuring a duration of time of charging the power source from the first state of charge to the upper voltage capacity value.

9. The method of claim 1, wherein the first parameter value comprises a unit of electric charge; and
wherein measuring the first parameter value comprises measuring an electrical current supplied to the power source during a time of charging the power source from the first state of charge to the upper voltage capacity value.

10. The method of claim 1, wherein measuring the overpotential value comprises:
ceasing the charging in response to charging the power source to the upper voltage capacity value;
implementing a delay in which the power source is neither charged nor discharged;
after the delay, measuring a second state of charge of the power source; and
determining the overpotential value via a difference between the upper voltage capacity value and the second state of charge.

11. The method of claim 1, wherein the power source comprises a solid-state battery.

12. A method for determining a degradation of a battery, the method comprising:
charging the battery over a plurality of charge cycles;
storing a plurality of charge capacity values over the plurality of charge cycles;
discharging the battery over a plurality of discharge cycles;
storing a plurality of discharge capacity values over the plurality of discharge cycles;
storing a plurality of overpotential values over one of the plurality of charge cycles and the plurality of discharge cycles;
determining a first comparison value between a first charge capacity value of the plurality of charge capacity values and a grouped value of a subset of charge capacity values of the plurality of charge capacity values;
determining a second comparison value between a first discharge capacity value of the plurality of discharge capacity values and a grouped value of a subset of discharge capacity values of the plurality of discharge capacity values;
determining a third comparison value between a first overpotential value of the plurality of overpotential values and a grouped value of a subset of overpotential values of the plurality of overpotential values; and
determining a degradation of the battery based on the first comparison value, the second comparison value, and the third comparison value.

13. The method of claim 12, wherein the grouped value of the subset of charge capacity values comprises an average of the subset of charge capacity values;
wherein the grouped value of the subset of discharge capacity values comprises an average of the subset of discharge capacity values; and
wherein the grouped value of the subset of overpotential values comprises an average of the subset of overpotential values.

14. The method of claim 12, wherein determining the degradation of the battery comprises determining the degradation based on:
the first comparison value being greater than the grouped value of the subset of discharge capacity values;
the second comparison value being less than the grouped value of the subset of discharge capacity values; and
the third comparison value being less than the grouped value of the subset of overpotential values.

15. A system comprising:
a DC power source;
a load; and
a controller configured to:
measure a first parameter value of the DC power source charging during each of a plurality of charge cycles;
control the load to discharge the DC power source over a plurality of discharge cycles;
measure a second parameter value of the DC power source discharging during each of a plurality of discharge cycles;
measure a third parameter value of the DC power source overvoltage after each of one of the plurality of charge cycles and the plurality of discharge cycles;
determine, based on each of the first, second, and third parameter values, a cell degradation of at least one cell of the DC power source.

16. The system of claim 15 further comprising a power supply;
wherein the controller is further configured to control the power supply to charge the DC power source over the plurality of charge cycles.

17. The system of claim 15, wherein the controller is further configured to:
store the measured first parameter value from each of the plurality of charge cycles in a set of historical first parameter values;
store the measured second parameter value from each of the plurality of discharge cycles in a set of historical second parameter values; and
store the measured third parameter value from each of the one of the plurality of charge cycles and the plurality of discharge cycles in a set of historical third parameter values.

18. The system of claim 17, wherein each historical first parameter value of the set of historical first parameter values comprises a charge time of the DC power source from a first respective minimum state of charge to a first respective maximum state of charge; and
wherein each historical second parameter value of the set of historical second parameter values comprises a discharge time of the DC power source from a second respective minimum state of charge to a second respective maximum state of charge.

19. The system of claim 17, wherein the controller, in being configured to determine the cell degradation, is configured to determine the cell degradation based on:
a first historical first parameter value of the set of historical first parameter values being higher than an average of a subset of the set of historical first parameter values;
a first historical second parameter value of the set of historical second parameter values being less than an average of a subset of the set of historical second parameter values; and
a first historical third parameter value of the set of historical third parameter values being less than an average of a subset of the set of historical third parameter values.

20. The system of claim 15, wherein the controller, in being configured to measure the third parameter value is configured to measure the third parameter value after a relaxation period following each of one of the plurality of charge cycles and the plurality of discharge cycles.
